(19) United States
(12) Patent Application Publication
(10) Pub. No.: US 2025/0113670 A1
(43) Pub. Date: Apr. 3, 2025

(54) CONNECTION STRUCTURE BETWEEN LIGHT EMITTING DIODE AND SUBSTRATE, AND DISPLAY MODULE INCLUDING SAME

(71) Applicant: SAMSONG ELECTRONICS CO., LTD., Suwon-si (KR)

(72) Inventors: Daesuck HWANG, Suwon-si (KR); Jaemoon LEE, Suwon-si (KR); Jeongyun KIM, Suwon-si (KR); Jinyoung KIM, Suwon-si (KR); Sungyong MIN, Suwon-si (KR); Changjoon LEE, Suwon-si (KR)

(73) Assignee: SAMSONG ELECTRONICS CO., LTD., Suwon-si (KR)

(21) Appl. No.: 18/970,469

(22) Filed: Dec. 5, 2024

Related U.S. Application Data
(63) Continuation of application No. PCT/KR2023/005997, filed on May 3, 2023.

(30) Foreign Application Priority Data
Jun. 29, 2022 (KR) 10-2022-0080061
Aug. 22, 2022 (KR) 10-2022-0105049

(51) Int. Cl. H10H 20/831; H10H 29/85

(52) U.S. Cl. CPC H10H 20/831; H10H 29/857

(57) ABSTRACT

A light emitting diode may include an emission layer, a first electrode on a first surface of the emission layer, and a second electrode on the first surface of the emission layer and spaced apart from the first electrode at an interval, wherein the first electrode and the second electrode protrude further than an outer portion of the light emitting layer.

### CROSS REFERENCE TO RELATED APPLICATIONS

This application is a continuation of International Application No. PCT/KR2023/005997, filed on May 3, 2023, which is based on and claims priority to Korean Patent Application No. 10-2022-0080061, filed on Jun. 29, 2022, in the Korean Intellectual Property Office, and Korean Patent Application No. 10-2022-0105049, filed on Aug. 22, 2022, in the Korean Intellectual Property Office, the disclosures of which are incorporated by reference herein in their entireties.

### BACKGROUND

### 1. Field

The present disclosure relates to a connection structure between light emitting diodes and a substrate, and a display module including the same.

### 2. Description of Related Art

A display may include a substrate on which a plurality of thin film transistors (TFTs) is provided and a plurality of light emitting diodes mounted to the substrate.

The plurality of light emitting diodes may be inorganic light emitting diodes that emit light on its own. The plurality of light emitting diodes may express various colors while being operated in a pixel or sub pixel unit. Operations of each pixel or sub pixel may be controlled by a plurality of TFTs. Each light emitting diode may emit lights of various colors, for example, light of a red color, a green color, or a blue color.

### SUMMARY

Additional aspects will be set forth in part in the description which follows and, in part, will be apparent from the description, or may be learned by practice of the presented embodiments.

According to an aspect of the present disclosure, a light emitting diode includes a light emitting layer, a first electrode on a first surface of the light emitting layer, and a second electrode on the first surface of the light emitting layer spaced apart from the first electrode at an interval. The first electrode and the second electrode protrude further than an outer portion of the light emitting layer.

The first electrode and the second electrode may protrude in a length direction of the light emitting layer.

A direction to which the first electrode protrudes may be opposite to a direction to which the second electrode protrudes.

The first electrode and the second electrode may be disposed on the light emitting layer symmetrically to each other.

At least one of the first electrode or the second electrode may protrude in a width direction of the light emitting layer.

At least one of a width of the first electrode or a width of the second electrode may be greater than a width of the light emitting layer.

At least one of a width of the first electrode or a width of the second electrode may be less than a width of the light emitting layer.

At least one of the first electrode or the second electrode may be a quadrangle type shape when viewed from a plane view.

At least one of a protrusion portion of the first electrode or a protrusion portion of the second electrode may be a trapezoidal shape when viewed from a plane view.

According to another aspect of the present disclosure, a display module includes a substrate including a plurality of substrate electrode pads on a first surface of the substrate, and a plurality of light emitting diodes including a plurality of electrodes connected to the plurality of substrate electrode pads. The plurality of light emitting diodes includes a pair of electrodes protruding further than an outer portion of a light emitting layer of a light emitting diode. The plurality of substrate electrode pads is a pair of substrate electrode pads that correspond to the pair of electrodes. The pair of substrate electrode pads and the pair of electrodes are electrically and physically connected via a stacked conductive material.

The pair of electrodes may protrude a length direction of the light emitting layer.

The pair of electrodes may include a first electrode and a second electrode, and a direction to which the first electrode protrudes may be opposite to a direction to which the second electrode protrudes.

The first electrode and the second electrode may be disposed on the light emitting layer symmetrically to each other.

At least one of the first electrode or the second electrode may protrude in a width direction of the light emitting layer.

At least one of the first electrode or the second electrode may protrude in the length direction of the light emitting layer.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram illustrating a display device according to one or more embodiments;

FIG. 2 is a plane view illustrating a display module according to one or more embodiments;

FIG. 3 is a plane view illustrating a pixel according to one or more embodiments;

FIG. 4 is a vertical cross-sectional view taken along line A-A′ shown in FIG. 3;

FIG. 5 is a side surface view illustrating a micro LED according to one or more embodiments;

FIG. 6 is a plane view illustrating the micro LED shown in FIG. 5;

FIG. 7 is a plane view illustrating a micro LED according to one or more embodiments;

FIG. 8 is a plane view illustrating a micro LED according to one or more embodiments;

FIG. 9 is a plane view illustrating a micro LED according to one or more embodiments;

FIG. 10 is a diagram illustrating connecting connection of a micro LED to a substrate according to one or more embodiments;

FIG. 11 is a diagram illustrating connecting connection of a micro LED to a substrate according to one or more embodiments;

FIG. 12 is a diagram illustrating connecting connection of a micro LED to a substrate according to one or more embodiments;

FIG. 13 is a diagram illustrating connecting connection of a micro LED to a substrate according to one or more embodiments; and

FIG. 14 is a diagram illustrating connecting connection of a micro LED to a substrate according to one or more embodiments.

### DETAILED DESCRIPTION

Various embodiments will be described in greater detail below with reference to the accompanied drawings. Embodiments described herein may be variously modified. A specific embodiment may be illustrated in the drawings and described in detail in the detailed description. However, the specific embodiment described in the accompanied drawing is only to assist in the easy comprehension of the various embodiments. Accordingly, it should be noted that the embodiments of the disclosure are not limited by the specific embodiments described in the accompanied drawings, and should be interpreted to include all equivalents or alternatives of the embodiments included in the spirit of the disclosure and in the technical scope.

Terms including ordinal numbers such as first and second may be used in describing the various elements, but the elements are not limited by the above-described terms. The above-described terms may be used only for the purpose of distinguishing one element from another element.

It is to be understood that the terms such as “have” or “include” are used herein to designate a presence of a characteristic, number, step, operation, element, component, or a combination thereof, and not to preclude a presence or a possibility of adding one or more of other characteristics, numbers, steps, operations, elements, components or a combination thereof. When a certain element is indicated as being “coupled with/to” or “connected to” another element, it may be understood as the certain element being directly coupled with/to the another element or as being coupled through other element. Conversely, when a certain element is indicated as “directly coupled with/to” or “directly connected to” another element, it may be understood as the other element not being present therebetween.

In the disclosure, the expression ‘same’ may refer to not only fully matching, but also include a difference of an extent that considers a processing error range.

In the disclosure, The term of “at least one of A, B, or C”, “at least one of A, B, and C”, and “and/or” includes a plurality of combinations of relevant items or any one item among a plurality of relevant items. For example, “at least one of A, B, or C” may include any and all of the combinations of A, B, and C, including A alone, B alone, C alone, only A and B, only A and C, only B and C, and all of A, B, and C.

In the disclosure, in case it is determined that the detailed description of related known technologies or configurations may unnecessarily confuse the gist of the disclosure, the detailed description thereof will be omitted.

According to one or more embodiments, a display module may include a plurality of light emitting diodes for image display. The display module may include a flat panel display panel or a curved display panel.

According to one or more embodiments, a light emitting diode included in the display module may be an inorganic light emitting diode having a size of less than or equal to 100 μm. For example, the inorganic light emitting diode may be a micro LED or a mini LED, but is not limited thereto. The inorganic light emitting diode may have longer brightness, light emitting efficiency, and lifespan than an organic light emitting diode (hereinafter, referred to as ‘OLED’). The inorganic light emitting diode may be a semiconductor chip capable of emitting light on its own when power is supplied. The inorganic light emitting diode may have a fast response rate, low power, and high luminance. If the inorganic light emitting diode is a micro LED, efficiency in converting electricity to photons may be higher compared to an LCD or an OLED. For example, the micro LED may have a higher “brightness per watt” compared to the LCD or the OLED. Accordingly, the micro LED may exhibit a same brightness with approximately half of the energy compared to the LED or the OLED that exceeds 100 μm. The micro LED may accurately express colors of a wide range and implement sharpness of a screen in even outdoors which is brighter than indoors due to being able to implement a high resolution, superior color, contrast, and brightness. The micro LED may have a long lifespan without deformation due to being resistant against a burn in phenomenon and having low heat generation.

According to one or more embodiments, the light emitting diode may be formed in a flip chip form in which an anode electrode and a cathode electrode are disposed at an opposite surface of a light emitting surface.

According to one or more embodiments, a substrate may be disposed with a TFT layer on which thin film transistor (TFT) circuitry is formed at a first surface (e.g., a front surface of the substrate). The substrate may be disposed with power supply circuitry which supplies power to the TFT circuitry at a second surface (e.g., a rear surface of the substrate) and a data driving driver, a gate driving driver, and a timing controller that controls each driving driver. The substrate may be arrayed with a plurality of pixels on a TFT layer. Each pixel may be driven by the TFT circuitry.

According to one or more embodiments, the TFT formed on the TFT layer may be a low-temperature polycrystalline silicon (LTPS) TFT, a low-temperature polycrystalline oxide (LTPO) TFT, or an oxide TFT

According to one or more embodiments, the substrate provided with the TFT layer may be a glass substrate, a synthetic resin based (e.g., polyimide (PI), polyethylene terephthalate (PET), polyethersulfone (PES), polyethylene naphthalate (PEN), polycarbonate (PC), etc.) substrate having flexibility, or a ceramic substrate.

According to one or more embodiments, the TFT layer of the substrate may be integrally formed with the first surface of the substrate, or manufactured as a separate film form and attached to the first surface of the substrate.

According to one or more embodiments, the first surface of the substrate may be divided into an active area and a non-active area. The active area may be an area that the TFT layer occupies from among a whole area of the first surface of the substrate. The non-active area may be an area excluding the active area from among the whole area of the first surface of the substrate.

According to one or more embodiments, an edge area of the substrate may be an outermost portion area of the substrate. For example, the edge area of the substrate may include an area corresponding to a side surface of the substrate, a portion of an area of the first surface of the substrate and a portion of an area of the second surface of the substrate which are respectively adjacent to each of the side surface thereof. At the edge area of the substrate, the TFT circuitry which is positioned at the first surface of the substrate and a plurality of side surface wirings which electrically connect driving circuitry positioned at the second surface of the substrate may be disposed.

According to one or more embodiments, the substrate may be formed into a quadrangle type. For example, the substrate may be formed into a rectangle or a square.

According to one or more embodiments, the TFT provided at the substrate may be implemented as, for example, oxide TFTs and Si TFTs (polysilicon, a-silicon), organic TFTs, graphene TFTs, etc. other than low-temperature polycrystalline silicon (LTPS) TFTs. The TFTs may be applied by making only a P-type (or an N-type) MOSFET in an Si wafer CMOS process.

According to one or more embodiments, the substrate included in the display module may omit the TFT layer on which the TFT circuitry is formed. In this case, a plurality of micro IC chips that functions as the TFT circuitry may be mounted at the first surface of the substrate. In this case, the plurality of micro IC may be electrically connected with the plurality of light emitting diodes arrayed at the first surface of the substrate through wiring.

According to one or more embodiments, a pixel driving method of the display module may be an active matrix (AM) driving method or a passive matrix (PM) driving method.

According to one or more embodiments, the display module may be applied installed in a wearable device, a portable device, a handheld device, and in electronic products or an electric field which require various displays.

According to one or more embodiments, by connecting the plurality of display module in a grid array, such as, for example, and without limitation, a monitor for a personal computer, a high-resolution television, and signage (or, a digital signage, an electronic display) may be formed.

According to one or more embodiments, one pixel may include a plurality of light emitting diodes. In this case, one light emitting diode may be a sub pixel. In the disclosure, one ‘light emitting diode’, one ‘micro LED’, and one ‘sub pixel’ may be used interchangeably as the same meaning.

One or more embodiment of the disclosure will be described in detail with reference to the accompanying drawings to aid in the understanding of those of ordinary skill in the art. However, the disclosure may be implemented in various different forms and it should be noted that the disclosure is not limited to an example described herein. In the drawings, parts not relevant to the description of the disclosure may be omitted to clearly describe an example of the disclosure, and like reference numerals may be used to indicate like elements throughout the whole of the disclosure.

A display device and a light emitting diode unit according to an example of the disclosure will be described with reference to the drawings below.

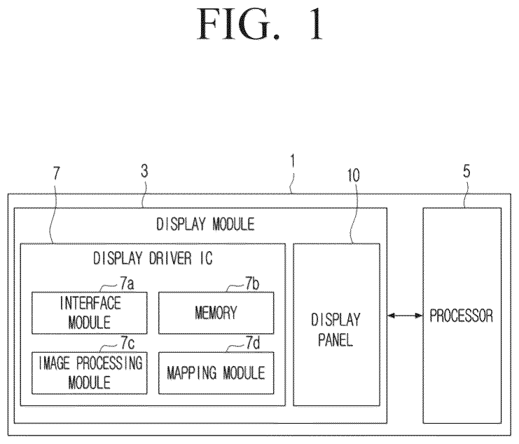

FIG. 1 is a block diagram illustrating a display device according to one or more embodiments.

Referring to FIG. 1, a display device 1 may include a display module 3 and a processor 5.

The display module 3 may display various images. Here, an image may be a concept that includes a still image and/or a moving image. The display module 3 may display various images such as, for example, and without limitation, a broadcast content, a multimedia content, and the like. In addition, the display module 3 may display a user interface and an icon.

The display module 3 may include a display panel 10 and a display driver integrated circuit (IC) 7 for controlling the display panel 10.

The display driver IC 7 may include an interface module 7A, a memory 7B (e.g., a buffer memory), an image processing module 7C, or a mapping module 7D. The display driver IC 7 may receive, for example, image data, or image information including an image control signal corresponding to a command for controlling the image data from other elements of the display device 1 through the interface module 7A. For example, the image information may be received from the processor 5 (e.g., a main processor (e.g., an application processor)) or an auxiliary processor (a co-processor) which is operated independently from the function of the main processor.

The display driver IC 7 may store at least a portion from among the received image information, for example, in frame units, in the memory 7B. The image processing module 7C may perform pre-processing or post-processing (e.g., adjustment of resolution, brightness, or size) of, for example, at least a portion of the image data based on a feature of the image data or a feature of the display panel 10. The mapping module 7D may generate a voltage value or a current value corresponding to the image data which was pre-processed or post-processed through the image processing module 7C. According to an example, the generation of the voltage value or the current value may be performed based at least in part on, for example, a feature of pixels (e.g., an array of pixels (a red/green/blue (a R/G/B) stripe structure or a R/G/B pentile stricture), or a size of each of the sub pixels in the display panel 10. Based on at least a portion of the pixels of the display panel 10 being driven based at least in part on, for example, the voltage value or the current value, visual information (e.g., texts, images, or icons) corresponding to the image data may be displayed through the display panel 10.

The display driver IC 7 may transmit, based on image information received from the processor 5, a driving signal (e.g., a driver driving signal, a gate driving signal, etc.) to a display.

The display driver IC 7 may display an image based on an image signal received from the processor 5. In an example, the display driver IC 7 may generate a driving signal of a plurality of sub pixels based on the image signal received from the processor 5, and display an image by controlling emission of light of the plurality of sub pixels based on the driving signal.

The display module 3 may further include touch circuitry. The touch circuitry may include a touch sensor and a touch sensor IC for controlling the touch sensor. The touch sensor IC may control the touch sensor to, for example, detect a touch input or a hovering input for a designated position of the display panel 10. For example, the touch sensor IC may detect the touch input or the hovering input by measuring a change in signal (e.g., voltage, an amount of light, resistance, or an electric charge) for the designated position of the display panel 10. The touch sensor IC may provide information (e.g., position, area, pressure, or time) on the detected touch input or hovering input to the processor 5. According to an example, at least a portion (e.g., touch sensor IC) of the touch circuitry may be included as a portion of the display driver IC 7, or the display panel 10, or as a portion of another element (e.g., auxiliary processor) disposed outside of the display module 3.

The processor 5 may be implemented as a digital signal processor (DSP) for processing a digital image signal, a microprocessor, a graphics processing unit (GPU), an artificial intelligence (AI) processor, a neural processing unit (NPU), or a time controller (TCON). However, the embodiment is not limited thereto, and may include one or more from among a central processing unit (CPU), a micro controller unit (MCU), a micro processing unit (MPU), a controller, an application processor (AP), a communication processor (CP), or an ARM processor, or may be defined by a relevant term. In addition, the processor 5 may be implemented as a System on Chip (SoC) or a large scale integration (LSI) in which a processing algorithm is embedded, and may be implemented in a form of an application specific integrated circuit (ASIC) or a field programmable gate array (FPGA).

The processor 5 may control hardware or software elements connected to the processor 5 by operating an operating system or an application program, and perform various data processing and computations. In addition, the processor 5 may perform processing by loading commands or data received from at least one from among other elements in a volatile memory, and store various data in a non-volatile memory.

The display module 3 may be a touch screen coupled with a touch sensor, a flexible display, a rollable display, and/or a three dimensional display.

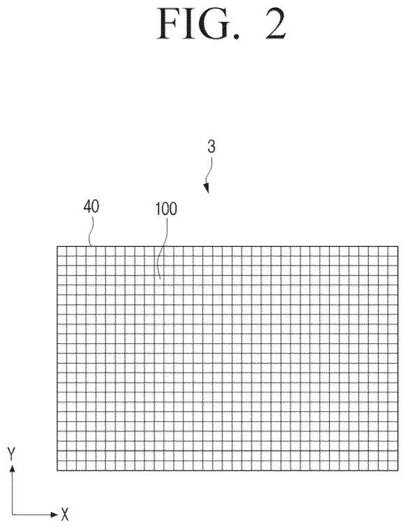

FIG. 2 is a plane view illustrating a display module according to one or more embodiments.

Referring to FIG. 2, the display module 3 may include a plurality of pixels 100 provided at the first surface of the substrate 40.

The substrate 40 may be provided with thin film transistor (TFT) circuitry which is electrically connected with the plurality of pixels 100 at the first surface thereof. The TFT provided at the substrate 40 may be an amorphous silicon (a-Si) TFT, a low temperature polycrystalline silicon (LTPS) TFT, a low temperature polycrystalline oxide (LTPO) TFT, a hybrid oxide and polycrystalline silicon (HOP) TFT, a liquid crystalline polymer (LCP) TFT, or an organic TFT (OTFT).

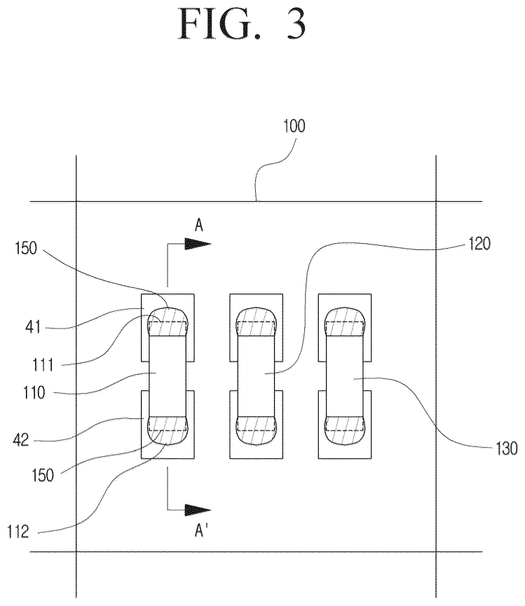

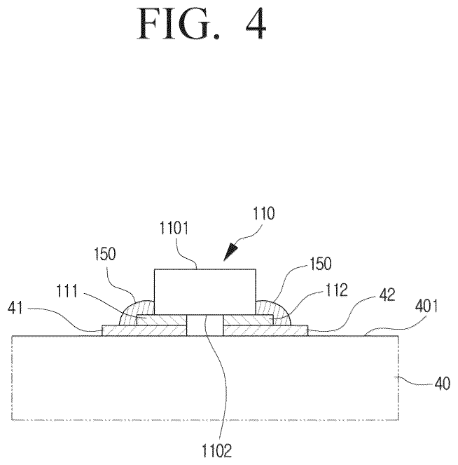

FIG. 3 is a plane view illustrating a pixel according to one or more embodiments. FIG. 4 is a vertical cross-sectional view taken along line A-A′ shown in FIG. 3.

One pixel 100 may correspond to one light emitting diode unit. Accordingly, reference number 100 which indicates ‘pixel’ in the disclosure may be used interchangeably as a reference numeral indicating the light emitting diode unit. The light emitting diode unit 100 may be, for example, a light emitting diode package.

A pixel 100 may include at least three sub pixels. A sub pixel may be, for example, a micro LED which is an inorganic light emitting diode. For convenience of description below, the sub pixel may be referred to as a micro light emitting diode (LED). Here, the micro LED may be defined as a LED with a size that is less than or equal to 100 μm or less than or equal to 30 μm.

Referring to FIG. 3 and FIG. 4, a pixel 100 may include three micro LEDs arrayed on the substrate 40. The three micro LEDs may include a first micro LED 110 that emits light of a red wavelength band, a second micro LED 120 that emits light of green wavelength band, and a third micro LED 130 that emits light of a blue wavelength band. The pixel 100 has been described as including three micro LEDs 110, 120, and 130 as an example, but is not limited thereto. For example, the pixel 100 may include one micro LED, or four or more micro LEDs.

The first micro LED 110, the second micro LED 120, and the third micro LED 130 may be disposed at the substrate 40 with a certain interval therebetween. The substrate 40 may be disposed with a plurality of TFTs for driving the first to third micro LED 110, 120, and 130. According to an example, the substrate 40 may be configured such that the plurality of TFTs is omitted and a plurality of micro ICs is disposed. The micro LED may perform the role of the TFT.

The first to third micro LED 110, 120, and 130 may be arrayed in a row with a certain interval therebetween within a pixel area divided on the substrate 40 as in FIG. 3, but is not limited thereto. For example, the first to third micro LED 110, 120, and 130 may be arrayed in an L-shape form, or arrayed in a pentile RGBG method. The pentile RGBG method may be a method in which a number of red, green, and blue sub pixels is arrayed in a 1:1:2 (RGBG) ratio using a cognitive feature of a person identifying a green color better than a blue color. The pentile RGBG method may increase yield and lower costs. The pentile RGBG method may implement high-resolution in a small screen.

A light emitting feature of the first micro LED 110 may be same as that of the second and third micro LEDs 120 and 130. Light emitted from the first micro LED 110 may be light having a same color as light emitted from the second and third micro LEDs 120 and 130. In an example, the first to third micro LED 110, 120, and 130 may all emit a blue light, a green light, or a red light. Accordingly, the pixel 100 may be configured such that a monochromatic light of red, green, or blue is emitted, or light in which the red, green or blue are mixed may be emitted

Referring to FIG. 4, a first substrate electrode pad 41 and a second substrate electrode pad 42 may be disposed at a first surface 401 of the substrate 40. The first substrate electrode pad 41 and the second substrate electrode pad 42 may be respectively contacted at a first electrode 111 and a second electrode 112 of the first micro LED 110. For example, the first substrate electrode pad 41 may be electrically and physically contacted with the first electrode 111 of the first micro LED 110 by a conductive material 150. The second substrate electrode pad 42 may be electrically and physically contacted with the second electrode 112 of the first micro LED 110 by the conductive material 150.

The first micro LED 110 may include a light emitting layer. A bottom surface (1102 in FIG. 2) of the light emitting layer may include the first electrode 111 and the second electrode 112. The ‘light emitting layer’ has been described as same as the ‘first micro LED 110’ below. The first electrode 111 and the second electrode 112 of the first micro LED 110 may be formed to protrude from both side surfaces of the first micro LED 110. Accordingly, when the conductive material 150 is deposited while the first micro LED 110 is transferred on the substrate 40, the first and second electrodes 111 and 112 of the first micro LED 110 may be connected with the first and second substrate electrode pads 41 and 42 of the substrate 40.

The conductive material 150 (e.g., molybdenum, titanium, tungsten, aluminum, or nickel) may directly connect the first and second electrodes 111 and 112 of the first micro LED 110 and the first and second substrate electrode pads 41 and 42 of the substrate 40. In this case, a connection between the first and second electrodes 111 and 112 of the first micro LED 110 and the first and second substrate electrode pads 41 and 42 of the substrate 40 may be formed as a stable path for conduction without interference of a separate material having insulating properties. As described above, if the first and second electrodes 111 and 112 of the first micro LED 110 and the first and second substrate electrode pads 41 and 42 of the substrate 40 are directly connected by the conductive material 150, a coupling stability between the first and second electrodes 111 and 112 of the first micro LED 110 and the first and second substrate electrode pads 41 and 42 of the substrate 40 according to external environment (e.g., changes in shrinkage and expansion according to physical impact and changes in temperature) may be improved and reliability of a product may be enhanced.

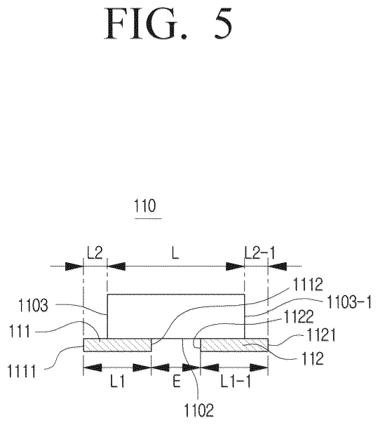

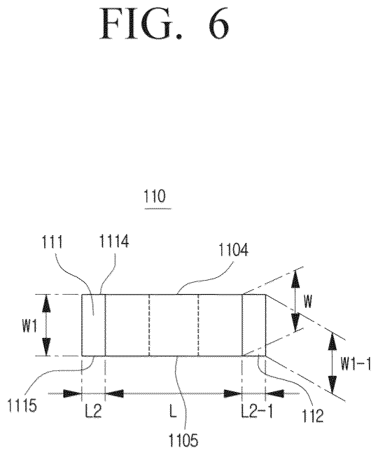

FIG. 5 is a side surface view illustrating a micro LED according to one or more embodiments. FIG. 6 is a plane view illustrating the micro LED shown in FIG. 5. According to one or more embodiments, structures of the first to third micro LED 110, 120, and 130 may be substantially the same. Accordingly, only the structure of the first micro LED 110 will be described below, and the ‘first micro LED 110’ will be referred to as a ‘micro LED 110’ for convenience of description.

Referring to FIG. 5 and FIG. 6, the micro LED 110 may be configured such that the first electrode 111 and the second electrode 112 are disposed at a bottom surface 1102 which is an opposite side of a light emitting surface 1101 (referring to FIG. 4) of the micro LED 110.

The first electrode 111 may be configured such that one side end 1111 is protruded from a first side surface 1103 of the micro LED 110 by a first protrusion length L2. The second electrode 112 may be configured such that a one side end 1121 is protruded from a second side surface 1103-1 by a second protrusion length L2-1. The second side surface 1103-1 of the micro LED 110 may be positioned at an opposite side of the first side surface 1103 of the micro LED 110.

If the micro LED 110 is transferred onto the substrate 40 as in FIG. 4, the first electrode 111 of the micro LED 110 may be disposed on the first substrate electrode pad 41, and the second electrode 112 of the micro LED 110 may be disposed on the second substrate electrode pad 42. In this case, as in FIG. 3, the first substrate electrode pad 41 may be configured such that a portion thereof is exposed to one side of the first electrode 111 of the micro LED 110, and the second substrate electrode pad 42 may be configured such that a portion thereof is exposed to one side of the second electrode 112 of the micro LED 110. The exposed portion of the first substrate electrode pad 41 may be connected with the first electrode 111 of the micro LED 110 by the conductive material 150, and the exposed portion of the second substrate electrode pad 42 may be connected with the second electrode 112 of the micro LED 110 by the conductive material 150. As described above, the first protrusion length L2 of the first electrode 111 of the micro LED 110 may be a length which is of an extent that can expose a portion of the first substrate electrode pad 41. The second protrusion length L2-1 of the second electrode 112 of the micro LED 110 may be a length which is of an extent that can expose a portion of the second substrate electrode pad 42.

The length L1 of the first electrode 111 of the micro LED 110 may be smaller than a length L of the micro LED 110. The length L1-1 of the second electrode 112 of the micro LED 110 may be smaller than the length L of the micro LED 110.

A sum of the length L1 of the first electrode 111 of the micro LED 110 and the length L1-1 of the second electrode 112 of the micro LED 110 may be greater than or equal to the length L of the micro LED 110.

A width W1 of the first electrode 111 of the micro LED 110 and a width W of the micro LED 110 may be the same. A width W1-1 of the second electrode 112 of the micro LED 110 and the width W of the micro LED 110 may be the same.

The first and second electrodes 111 and 112 of the micro LED 110 are not limited to the shapes shown in FIG. 5 and FIG. 6. For example, the first and second electrodes 111 and 112 of the micro LED 110 may have shapes that are respectively protruded to the first and second side surfaces 1103 and 1103-1 of the first micro LED 110, and may be any shape so long as it is a shape that has a length which is of an extent that can expose portions of the first and second substrate electrode pads 41 and 42.

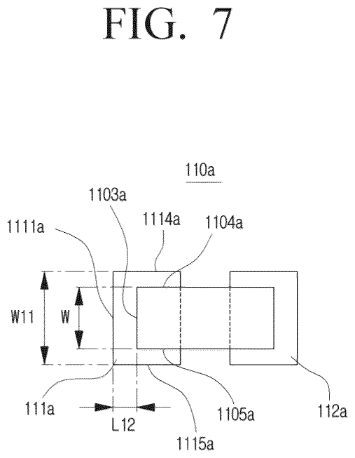

FIG. 7 to FIG. 9 are plane views illustrating a micro LED according to one or more embodiments. Examples for shapes of the first and second electrodes 111 and 112 of the micro LED 110 will be described below with reference to the drawings.

Referring to FIG. 7, a first electrode 111a and a second electrode 112a of a micro LED 110a may have a rectangular or a square shape which are protruded from each side surface of the micro LED 110a when viewed from a plane view.

The first electrode 111a of the micro LED 110a may be formed so as to protrude toward each of a first side surface 1103a, a third side surface 1104a, and a fourth side surface 1105a of the micro LED 110a. The first electrode 111a of the micro LED 110a may be configured such that a first side end 1111a is protruded from a first side surface 1103a of the micro LED 110a by a first protrusion length L12. A third side end 1114a and a fourth side end 1115a that respectively extend from both sides of the first electrode 111a of the micro LED 110a may be respectively protruded from the third side surface 1104a and the fourth side surface 1105a of the micro LED 110a by a predetermined length, respectively. Accordingly, a width W11 of the first electrode 111a of the micro LED 110a may be greater than a width W of the micro LED 110a.

The second electrode 112a of the micro LED 110a may be disposed symmetrically to the first electrode 111a. In this case, the second electrode 112a of the micro LED 110a may be configured such that three side ends thereof are protruded from corresponding side surfaces of the micro LED 110a by a predetermined length, respectively, similarly with the first electrode 111a.

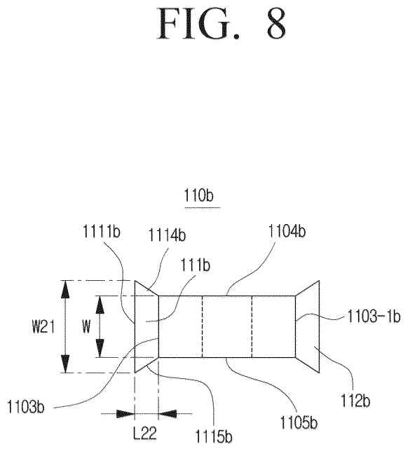

Referring to FIG. 8, a micro LED 110b may be configured such that a first electrode 111b is protruded from a first side surface 1103b of the micro LED 110b by a first protrusion length L22. In this case, the first electrode 111b of the micro LED 110b may be configured such that a portion protruded from the micro LED 110b may have a shape in which the width thereof becomes gradually wider as the protruded portion is further distanced from the micro LED 110b.

The first electrode 111b of the micro LED 110b may be configured such that a third side end 1114b and a fourth side end 1115b that respectively extend from both sides of a first side end 1111b are respectively disposed to be inclined. Accordingly, a width W21 of the first electrode 111a of the micro LED 110a may be greater than a width W of the micro LED 110b. In this case, a shape of a portion protruded from the first side surface 1103a of the micro LED 110b may be a rough trapezoidal shape.

A second electrode 112b of the micro LED 110b may be disposed symmetrically to the first electrode 111b. In this case, the second electrode 112b of the micro LED 110b may be configured such that a shape of a portion protruded from a second side surface 1103-1b of the micro LED 110b is a rough trapezoidal shape similarly with the first electrode 111b.

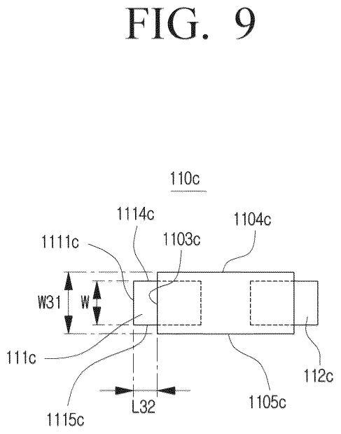

Referring to FIG. 9, a first electrode 111c and a second electrode 112c of a micro LED 110c may be a rectangular or a square shape when viewed from a plane view.

The first electrode 111c of the micro LED 110c may be formed to protrude from a first side surface 1103c of the micro LED 110c by a first protrusion length L32. In this case, a third side end 1114c and a fourth side end 1115c that respectively extend toward both sides of the first electrode 111c of the micro LED 110c may be inserted respectively from a third side surface 1104c and a fourth side surface 1105c of the micro LED 110a toward an inner side of the micro LED 110c by a predetermined length, respectively. Accordingly, a width W31 of the first electrode 111c of the micro LED 110c may be smaller than a width W of the micro LED 110c.

In FIG. 8, the third side end 1114c and the fourth side end 1115c of the micro LED 110c have been shown in a structure inserted toward an inner side of the micro LED 110c than the third side surface 1104c and the fourth side surface 1105c of the micro LED 110a, respectively, but is not limited thereto. For example, the third side end 1114c and the fourth side end 1115c of the micro LED 110c may be at a position corresponding respectively to the third side surface 1104c and the fourth side surface 1105c of the micro LED 110a. The third side end 1114c of the micro LED 110c may be protruded from the third side surface 1104c of the micro LED 110a by a predetermined length. The fourth side end 1115c of the micro LED 110c may be protruded from the fourth side surface 1105c of the micro LED 110a by a predetermined length.

As described, the micro LED according to one or more embodiments may have various shapes when viewed from the plane views of the first electrode and the second electrode under the structure of the first electrode and the second electrode being respectively further protruded than the first side end and the second side end of the micro LED.

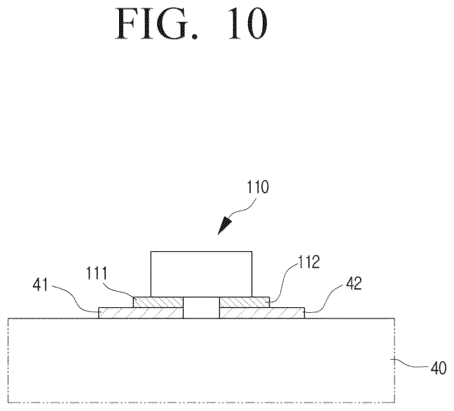

An example of the micro LED 110 being connected to the substrate 40 according to one or more embodiments will be described below with reference to the drawings. FIG. 10 to FIG. 14 are diagrams illustrating an example of connecting a micro LED to a substrate according to one or more embodiments.

Referring to FIG. 10, the micro LED 110 may be transferred on the substrate 40. A method of transferring the micro LED 110 to the substrate 40 may be performed in various methods such as, for example, and without limitation, a laser transfer method, a stamping transfer method, a rollable transfer method, and the like.

The micro LED 110 transferred on the substrate 40 may be configured such that the first electrode 111 is placed on a top surface of the first substrate electrode pad 41, and the second electrode 112 is placed on a top surface of the second substrate electrode pad 42. In this case, a portion of the first substrate electrode pad 41 may not be covered by the first electrode 111 and exposed, and a portion of the second substrate electrode pad 42 may not be covered by the second electrode 112 and exposed.

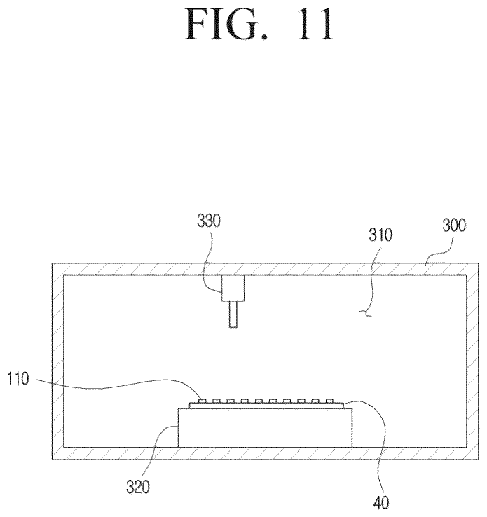

Referring to FIG. 11, the substrate 40 on which the micro LED 110 is transferred may be loaded in a chamber 300 for a connection process. The substrate 40 may be placed at a stage 320 disposed inside of the chamber 300. The substrate 40 may be stably fixed at the stage 320 by a clamping device provided at the stage 320.

The chamber 300 may have a laser irradiating device 330 for irradiating a laser beam 331 to an upper part inside thereof disposed in a movable state in an X-axis, Y-axis, and a Z-axis direction. In this case, at the inside of the chamber 300, a driving device including a plurality of motors, a plurality of linear guide devices, and the like may be provided for the laser irradiating device 330 to be driven along the three axes direction.

A connection process between the first and second electrodes 111 and 112 of the micro LED 110 and the first and second substrate electrode pads 41 and 42 of the substrate may be carried out by, for example, a laser chemical vapor deposition method. At an inner space 310 of the micro LED 110 a gas including a conductive material may be injected.

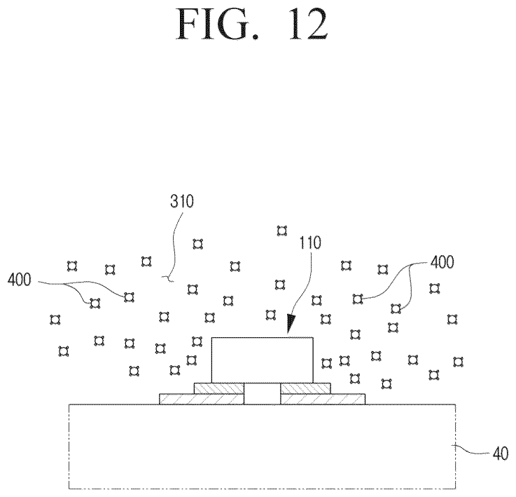

Referring to FIG. 12, a precursor 400 which is a conductive material may be injected in the inner space 310 of the chamber 300 at a predetermined concentration. The conductive material included in the gas may be molybdenum, titanium, tungsten, aluminum, or nickel.

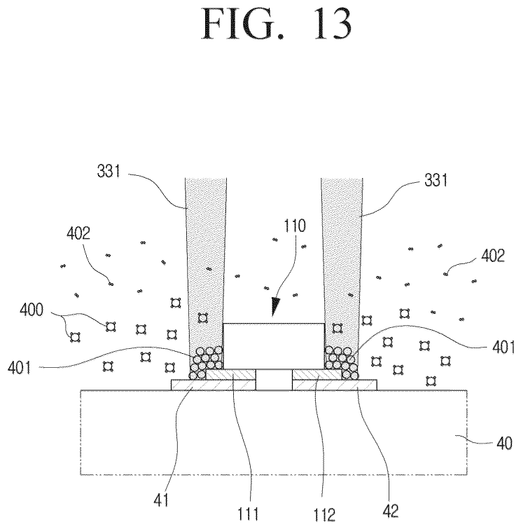

Referring to FIG. 13, the laser beam 331 is irradiated limited to the first electrode 111 and the second electrode 112 protruded from a side surface of the micro LED for the micro LED 110 and the substrate 40 to be electrically and physically interconnected. In this case, the precursor 400 may be changed to a metal material 401 in an area in which the laser beam 331 is irradiated, deposited on the first electrode 111 and the first substrate electrode pad 41, and deposited on the second electrode 112 and the second substrate electrode pad 42. Byproducts 402 that are generated in the deposition process as described above may be removed.

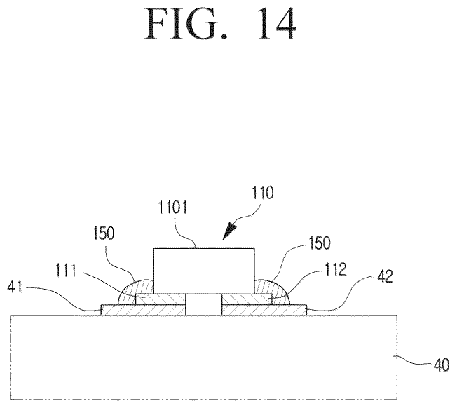

Referring to FIG. 14, between the first electrode 111 and the first substrate electrode pad 41 and between the second electrode 112 and the second substrate electrode pad 42, an electrical and physical connection may be carried out. Accordingly, an example according to the disclosure describes of a path for conduction of the micro LED 110 and the substrate 40 being stably formed without interference of a separate material having insulating properties.

While example embodiments of the disclosure have been shown and described, the disclosure is not limited to the aforementioned specific embodiments, and it is to be understood that various modifications may be made by those having ordinary skill in the technical field to which the disclosure belongs, without departing from the gist of the disclosure as claimed by the appended claims. Further, it is intended that such modifications are not to be interpreted independently from the technical idea or prospect of the disclosure.

What is claimed is:

1. A light emitting diode, comprising:
a light emitting layer;
a first electrode on a first surface of the light emitting layer; and
a second electrode on the first surface of the light emitting layer and spaced apart from the first electrode at an interval,
wherein the first electrode and the second electrode protrude further than an outer portion of the light emitting layer.

2. The light emitting diode of claim 1, wherein the first electrode and the second electrode protrude in a length direction of the light emitting layer.

3. The light emitting diode of claim 1, wherein a direction to which the first electrode protrudes is opposite to a direction to which the second electrode protrudes.

4. The light emitting diode of claim 1, wherein the first electrode and the second electrode are disposed on the light emitting layer symmetrically to each other.

5. The light emitting diode of claim 1, wherein at least one of the first electrode or the second electrode protrudes in a width direction of the light emitting layer.

6. The light emitting diode of claim 1, wherein at least one of a width of the first electrode or a width of the second electrode is greater than a width of the light emitting layer.

7. The light emitting diode of claim 1, wherein at least one of a width of the first electrode or a width of the second electrode is less than a width of the light emitting layer.

8. The light emitting diode of claim 1, wherein at least one of the first electrode or the second electrode is a quadrangle type shape when viewed from a plane view.

9. The light emitting diode of claim 1, wherein at least one of a protrusion portion of the first electrode or a protrusion portion of the second electrode is a trapezoidal shape when viewed from a plane view.

10. A display module, comprising:
a substrate comprising a plurality of substrate electrode pads on a first surface of the substrate; and
a plurality of light emitting diodes comprising a plurality of electrodes connected to the plurality of substrate electrode pads,
wherein the plurality of light emitting diodes comprises a pair of electrodes protruding further than an outer portion of a light emitting layer of a light emitting diode,
wherein the plurality of substrate electrode pads is a pair of substrate electrode pads that correspond to the pair of electrodes, and
wherein the pair of substrate electrode pads and the pair of electrodes are electrically and physically connected via a stacked conductive material.

11. The display module of claim 10, wherein the pair of electrodes protrude a length direction of the light emitting layer.

12. The display module of claim 11, wherein the pair of electrodes comprise a first electrode and a second electrode, and
wherein a direction to which the first electrode protrudes is opposite to a direction to which the second electrode protrudes.

13. The display module of claim 12, wherein the first electrode and the second electrode are disposed on the light emitting layer symmetrically to each other.

14. The display module of claim 12, wherein at least one of the first electrode or the second electrode protrude in a width direction of the light emitting layer.

15. The display module of claim 12, wherein at least one of the first electrode or the second electrode protrude in the length direction of the light emitting layer.
